(19) United States
(12) Patent Application Publication
(10) Pub. No.: US 2005/0173714 A1
(43) Pub. Date: Aug. 11, 2005

(54) Lighting system with high and improved extraction efficiency

(76) Inventors: Ho-Shang Lee, El Sobrante, CA (US); Alexander Birman, Oakland, CA (US)

Correspondence Address: PARSONS HSUE & DE RUNTZ LLP, 655 MONTGOMERY STREET, SUITE 1800, SAN FRANCISCO, CA, 94111, US

(21) Appl. No.: 10/892,856

(22) Filed: Jul. 16, 2004

Related U.S. Application Data
(63) Continuation-in-part of application No. 10/773,943, filed on Feb. 6, 2004.

(51) Int. Cl. H01L 21/00; H01L 33/00

(52) U.S. Cl. 257/84; 257/98; 438/24; 438/29

(57) ABSTRACT

In an epitaxial structure of a solid state lighting system, electrical current injection into the active layer is used to excite the photon emission. The present invention employs a unique waveguide layer in the epitaxial structure for trapping the light generated by the active layer in the fundamental waveguide mode. Multiple photonic crystal regions with different characteristics located either outside or inside one or more current injection regions extract photons from the waveguide layer(s). The present invention creates solid state lighting with high optical output and high power efficiency.

### CROSS-REFERENCE TO RELATED APPLICATION:

This application is a continuation-in-part application of U.S. patent application Ser. No. 10/773,943 filed Feb. 6, 2004, entitled “SOLID STATE LIGHTING SYSTEM WITH HIGH EXTRACTION EFFICIENCY” by Ho-Shang Lee and Alexander Birman, herein referred to as the “Parent Application”. The Parent Application is herein incorporated herein by reference in its entirely.

### BACKGROUND OF THE INVENTION

Rapid advances in solid state lighting systems such as high-brightness Light emitting diode (HB-LED) technology in the last decade have opened up the possibility of using LEDs as sources of general illumination in the not-too-distant future. Remarkable progress in LED efficiency, lifetime and total lumen output has enabled an early market in niche lighting applications such as traffic lights, brake lights, mobile phones, and outdoor signs. The rapid progress in LED technology has led to the belief that LED could have a significant impact on the lighting market within the next ten years. Illumination accounts directly for about 20% of U.S. electricity consumption. With advanced LED technology, the energy consumption can be reduced significantly.

The key components of the luminous performance are the internal quantum efficiency and the extraction efficiency. Utilizing high quality material and advanced epitaxial growth technologies such as Molecular Beam Epitaxy (MBE) and Metal-Organic Chemical Vapor Deposition (MOCVD) to facilitate band gap engineering such as Multiple Quantum Wells (MQWs) structure, the internal quantum efficiency is approaching 100%. In contrast, the extraction efficiency still needs much improvement. The extraction efficiency is the fraction of generated light that escapes from the semiconductor chip into the surrounding air or encapsulating epoxy, and is the fraction that is useful for illumination and other purposes. This is a challenging problem because the chip may have a much higher index of refraction, typically 3.4 for GaAs-based material, compared with 1.0 for air and approximately 1.5 for epoxy. This results in a critical angle of 17 degrees for air and 26 degrees for epoxy. If we consider a single surface, the light can only escape if it strikes the surface within the critical angle. Therefore, the extraction efficiency out of a single surface is only 2.2% into air and 4% into epoxy. The rest of light is reflected from the surface back into the active layer and reabsorbed by the semiconductor material or reflected at other surfaces.

The extraction efficiency is one of the main themes for improving the energy efficiency of LED. Methods such as random surface texture, grating thin film (U.S. Pat. No. 5,779,924), modifying chip geometry using, for example, truncated inverted pyramid (U.S. Pat. No. 6,323,063) and photonic crystal structure (U.S. Pat. No. 5,955,749 & U.S. patent application No. US2003/014150) are implemented. None of these approaches is entirely satisfactory. It is therefore desirable to provide an improved LED. with better characteristics.

### SUMMARY OF THE INVENTION

The present invention proposes a novel configuration for the solid state lighting systems to achieve extraction efficiency and optical emission from electrical pumping in the active layer superior to the above-mentioned conventional methods.

In an epitaxial structure of a solid state Light Emitting system, electrical current injection into the active layer is used to excite the photon emission. The invention of the parent application employs one or more structures (such as layers) different from the active layer for trapping the light generated by the active layer. Then another structure is used for extracting the light trapped. In one embodiment, the light generated by the active layer is trapped by means of a unique waveguide layer in the epitaxial structure to achieve high performance. The waveguide layer preferably traps a significant portion of the radiation generated by the active layer in a single mode (e.g. its fundamental mode) or a few lower-order modes. This feature of the parent application is a completely new feature in solid state lighting system design. Furthermore, one embodiment of the parent application employs multiple photonic crystal regions located either outside or inside one or more current injection regions to extract photons from the waveguide layer(s). This novel design optimizes the interplay of electrical pumping, radiation and optical extraction to increase the optical output to several times that of conventional solid state lighting systems. In another embodiment of the parent application, a transparent and conductive ITO layer is added to the surface of an epitaxial structure to reduce the interface reflection in addition to functioning as a current spreading layer. Each of the above-described features can be used separately or in conjunction with any one of the other features for improved performance. The invention of the parent application creates solid state lighting systems with high optical output and high power efficiency.

Thus, according to an embodiment of another aspect of the invention of the parent application, the radiation generated by an active layer in a semiconductor structure in response to current injection is trapped, preferably in a single mode or a few lower-order modes, and the trapped radiation is extracted, preferably by means other than the means used to trap the radiation. In one embodiment of the parent application, the trapping is performed by means of a waveguide layer which traps the radiation in its fundamental mode or a few lower-order modes. The extraction is preferably performed by means of photonic crystal structures. The present invention presents several novel configurations of photonic crystal structure for optimizing the light extraction efficiency. In one embodiment, a plurality of photonic crystal arrays with different parameters are employed. For example, the parameters may include array pattern, orientation relative to direction of light emitted by the active layer, lattice constants and indices of refraction of materials and size of the elements in the array.

### BRIEF DESCRIPTION OF THE DRAWINGS

FIG. 1 is a cross-sectional view that shows an epitaxial structure having a waveguide structure and suitable for implementing a photonic crystal structure to illustrate an embodiment of the invention of the parent application;

FIG. 2 is a cross-sectional view that shows that the holes are drilled through the epitaxial layers of the structure of FIG. 1 by a process such as chemical etching to improve light extraction;

FIGS. 3A-3D show the arrangement of photonic crystal pattern and current electrodes from the wafer level to the individual hole for LEDs to illustrate an embodiment of the invention of the parent application;

FIG. 4A is a cross-sectional view that shows one embodiment with electrode region overlapping a part of photonic crystal region;

FIG. 4B is a cross-sectional view that shows another embodiment with the current injection regions substantially segregated from the photonic crystal regions;

FIG. 5A shows an example of a single hexagonal cell in a chip surrounded by three different types of photonic crystal structures to illustrate an embodiment of the invention.

FIGS. 5B and 5C are schematic views of two different types of photonic crystal structures in FIG. 5A with different orientations but substantially the same lattice constant.

FIG. 5D is a schematic view of two different types of photonic crystal structures in FIG. 5A with different lattice constants but substantially the same orientation.

FIG. 6A shows an example of a single hexagonal cell in a chip surrounded by three different types of photonic crystal structures where a third type of photonic crystal structure acting as a reflector is implemented in the outside frame of the chip to reflect un-extracted light back towards the photonic crystal structures closer to the cell.

FIGS. 6B and 6C are schematic views of two different types of photonic crystal structures in FIG. 6A with different orientations but substantially the same lattice constant.

FIG. 6D is a schematic view of the photonic crystal structures in the outside frame of the chip in FIG. 6A with a lattice constant different from that in FIGS. 6B and 6C.

FIGS. 7A-7E illustrate a process for depositing metal layer as reflectors located near or at the edges of a chip to illustrate an embodiment of the invention.

FIG. 8A shows an example of a chip with a plurality of photonic crystal structures surrounded by current injection regions and another region of photonic crystal structures of a different type to illustrate another embodiment of the invention for optimizing light extraction.

FIGS. 8B and 8C are schematic views of the two different types of photonic crystal structures in FIG. 8A with different orientations but substantially the same lattice constant.

FIG. 9A shows an example of a chip with a plurality of photonic crystal structures of two different types arranged in columns and surrounded by current injection regions to illustrate another embodiment of the invention for optimizing light extraction to illustrate yet another embodiment of the invention.

FIGS. 9B and 9C are schematic views of the two different types of photonic crystal structures in FIG. 9A with different orientations but substantially the same lattice constant.

FIG. 10 is a schematic view of a device with multiple chips emitting light of different colors.

For simplicity in description, identical components are labeled by the same numerals in this application.

### DETAILED DESCRIPTION OF THE INVENTION

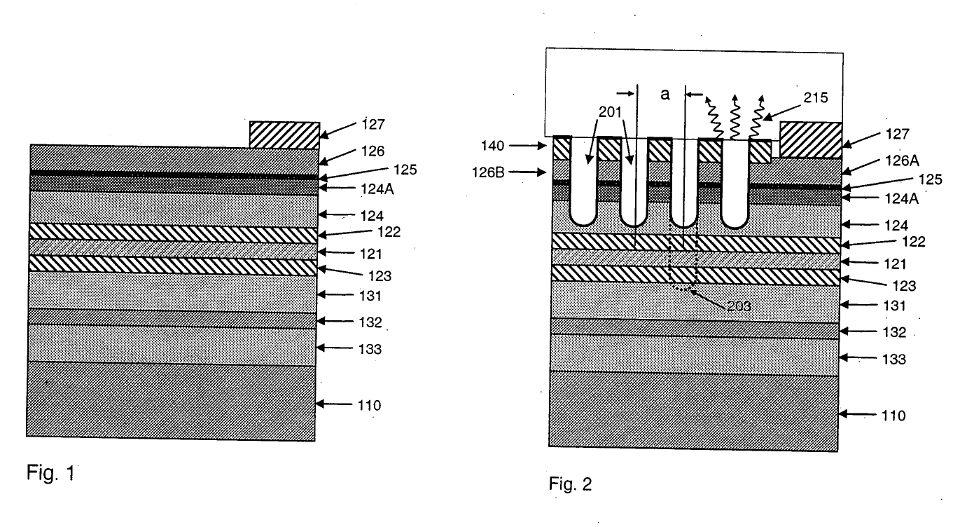

In order to illustrate one embodiment of the invention of the parent application directed to a solid state lighting system having a photonic crystal (PC) structure with clarity, we first present an epitaxial structure suitable for implementing photonic crystal and then add the photonic crystal structure into the epitaxial structure. FIG. 1 shows the epitaxial structure of the present invention without the PC structure. All epitaxial layers are grown on the top of the substrate 110. The substrate material is typically GaAs for red or yellow light emission structures and Sapphire, GaN or SiC for UV, blue and green light emission structures. Layer 121 is the active layer, where holes and electrons combine to emit light. The epitaxial structure of active layer 121 can be double heterostructure, multi-quantum wells (MQWs), or multi-quantum dots (MQDs) to optimize the internal quantum efficiency.

Holes and electrons combine in the active layer 121, causing light to be spontaneously generated from the layer. Then a large portion of emitted photons from the active layer 121 is trapped within the waveguide layers 122 and 123 and the active layer 121. Active layer 121 alone cannot serve as a waveguide core layer because usually it is very thin. In the present invention we arrange one or two additional waveguide layers with the refractive index close to that of the active layer and with the appropriate thickness. The index of refraction of the waveguide layers 122 and 123 is higher than that of the cladding layers 124 and 131, whose thickness(es) is more than 50 nm. The un-trapped light exits the semiconductor surfaces or is re-absorbed by the semiconductor structure in the same manner as in conventional LEDs. The waveguide layers, 122 and 123, are designed to allow the optical power to travel along the waveguide in one single mode or a few lower-order modes. To achieve such result, the thickness(es) of each of waveguide layers 122 and 123 is about 20 nm to 250 nm depending on the thickness of the active layer as well as the epitaxial structure. The waveguide layers can be degenerated if the active layer is thick enough in an unusual case. Extraction by Photonic Crystal will not be effective if the waveguide supports a number of modes with quite different propagation constants because the band edge of PC structure may correspond to only one mode or a few modes. Prior LED epitaxial structures, such as the ones in Patent Application US 2003/0141507, do not contain any waveguide layer like the ones in embodiments of the present invention.

Layer 124A in FIG. 1 is a contact layer to provide a transition to an ultra thin metal layer 125, which is followed by an Indium Tin Oxide (ITO) layer 126. ITO layer 126 and Ultra thin metal layer 125 are used to increase current spreading over the wafer surface. Current spreading layers for LEDs are described in U.S. patent application, Ser. No. 10/641,641, filed Aug. 14, 2003, which application is incorporated by reference herein in its entirety. The ITO is transparent and conductive and its index of refraction is about 1.8. It also acts as an antireflection coating to reduce the Fresnel reflection at the air interface or the interface to external media such as encapsulating epoxy. Generally the Fresnel reflection at semiconductor epitaxial-air interface is high due to high index of semiconductor materials, which results in about 17% reflection at GaN-based material-air interface and 30% reflection at GaAs-based material-air interface. Therefore the ITO layer 126 plays a significant role on enhancing the optical output. Other conductive and transparent material, which has index of refraction lower than those of semiconductor layers, can be used to replace ITO as the material used for the current spreading layer which also reduces Fresnel reflection.

For minimizing reflection from the interface with air or other media, the thickness of ITO layer 126 is preferably equal to λ/(4 nᵢₜₒ) , where λ is wavelength and nᵢₜₒ is the index of refraction of the ITO. The thickness of the ITO layer is about 89 nm for 640 nm optical emission and 65 nm for 470 nm optical emission. The thickness of ITO can range from 30 nm to 300 nm to cover emission from ultra-UV to near infrared. For some cases in the present invention, the ITO layer 126 and the ultra-thin metal layer 125 can be omitted without adversely affecting the extraction, but with lower optical output due to high reflection at the epitaxy-air interface. After the wafer epitaxial growth and/or the photonic crystal structure have been completed or formed, metal electrode 127 is deposited. The injection current from the electrode 127 flows through the active layer to electrically pump it to radiate. To reduce the loss of optical power through the substrate 110, a Distributed Bragg Reflector (DBR) layer 133 can be implemented to reflect the photons upward towards electrode 127. This layer 133 can be omitted without affecting the emission function of the solid state light emitting system. Buffer layer 132 is to provide a transition from the cladding layer 131 to the DBR layer 133. In view of the carrier transport in semiconductors, all semiconductor layers above the active layer 121 as shown in FIG. 1 can be either N-type or P type. The type of the semiconductor layers beneath the active layer 121 should be complementary to that above the active layer.

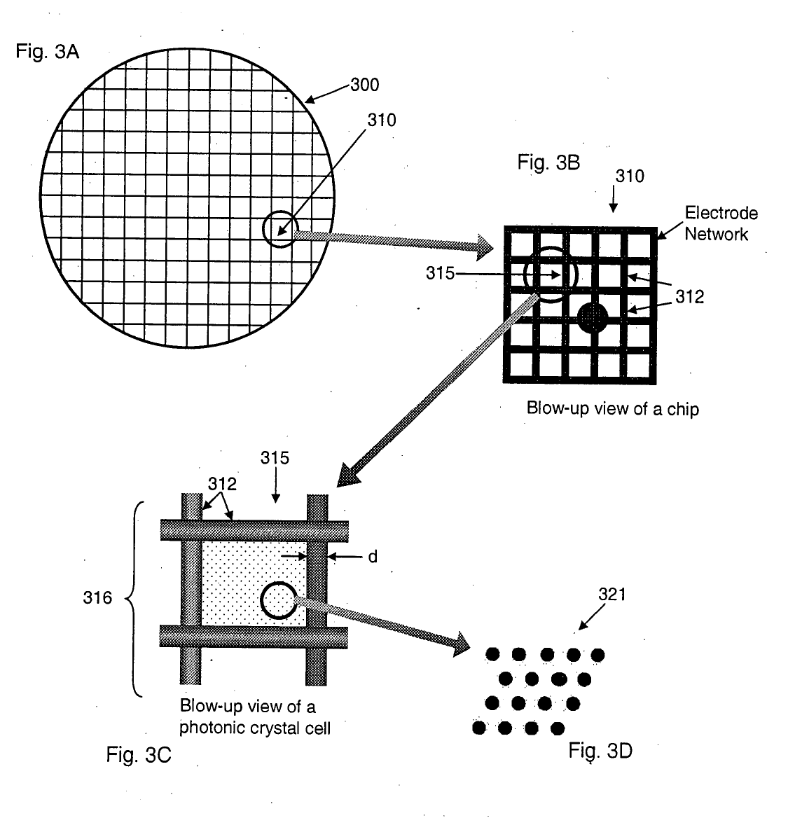

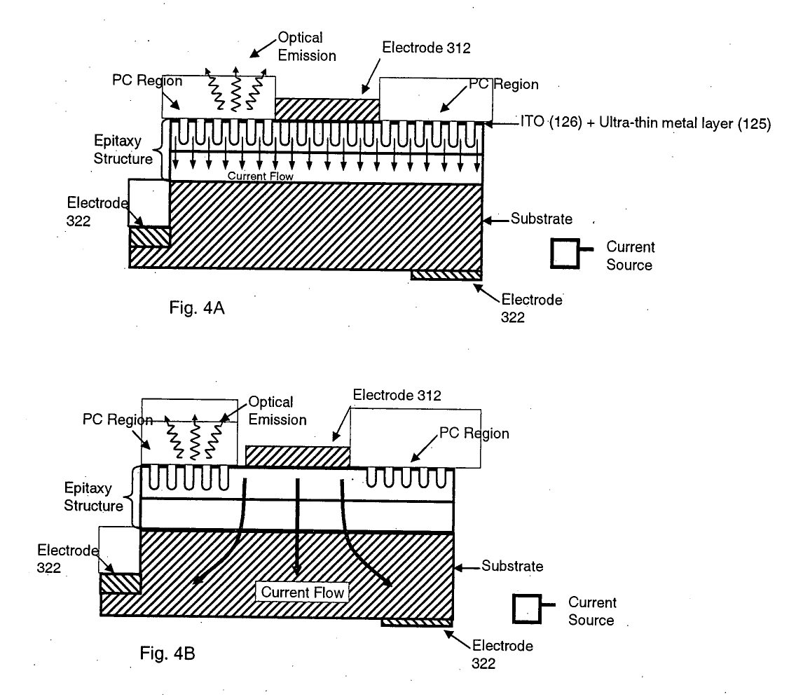

FIG. 2 and FIG. 3 show how a light extraction structure can be implemented in conjunction with the waveguide structure for improved performance. In one embodiment, this light extraction structure comprises a photonic crystal structure. This structure of one embodiment of the present invention is created, starting with the structure in FIG. 1, for improved light extraction. The photonic crystal structure comprises many holes through some of the layers drilled into the epitaxial structure of the solid state light emitting system in FIG. 1, where the holes preferably form a two-dimensional pattern. The present invention illustrates novel patterns for optimizing light extraction. In one embodiment, the electrode region superposes a part of the photonic crystal region as shown in FIG. 4A. The injection current supplied from the electrode and current source (connection between the source and the electrodes not shown) is intended to spread out through the ITO layer over the full PC region as shown in FIG. 4A. In another embodiment, the optical extraction region where the PC is located is substantially separated from the current injection region as shown in FIG. 4B. Holes 201 in FIG. 2 are preferably created by chemical etching. The hole etching or drilling can be stopped at cladding layer 124 or waveguide layer 122 or the drilling or etching can even punch holes through the active layer 121 and waveguide layer 123 as indicated by dotted line 203. The hole diameter is in the range of 50 nm to 300 nm (nano-meters) for visible light. The lattice constant a of the PC, the distance from the center of a hole to the center of the adjacent hole in the lattice of the PC, is from 80 nm to 600 nm for visible light. The lattice constant generally increases with the emitting wavelength and with the band number of the PC structure. The electrical field extending from the active layer 121 to the cladding layers 124 and 131, which is induced by the collective photons produced in the active layer 121, strongly interacts with the PC structure. At certain values for parameters of PC structure such as lattice constant and hole diameter as indicated below, the PC structure inhibits the photons from residing in the waveguide but emit out of the wafer surface as indicated by 215 in FIG. 2.

FIG. 2 shows that the holes 201 are drilled from the top of the wafer. But when the wafer bonding technique is used, the holes can be imbedded from layers 131 or 123 or even through the active layer 121 into waveguide layer 122 and cladding layer 124. Wafer bonding technique is to flip over the epitaxial structure by taking out the original substrate such as 110 and then bond a new substrate on the original top layer such as the layer 124 if the ITO layer 126 in FIG. 2 is omitted. If the new substrate has a band gap that is wider than that of the active layer, the photons emitted by the active layer will not be significantly absorbed by the new substrate, so that light can be emitted from both sides of the solid state light emitting system. This may be advantageous for some applications. For example, where GaAs is the material in the original substrate for the solid state light emitting system, a material with a band gap that is wider than that of GaAs may be used, such as GaP.

FIGS. 3A-3D are schematic views showing the arrangements of photonic crystal pattern and current electrodes from the wafer level to the individual hole that can be used in the solid state light emitting system of FIGS. 1, 2, 4A and 4B. In lighting applications, the wafer 300 in FIG. 3A is broken into many chips 310, one of which is shown as indicated by the blow-up view of FIG. 3B. Each chip 310 has a side with length in the range of 50 to 500 μm. Within each chip 310, an electrode network 312 run across the chip surface vertically and horizontally to spread current more evenly. Each of the networks 312 may have a grid-shaped pattern as shown in FIG. 3B, where the pattern is formed by interconnected vertical and horizontal electrically conductive strips. Each of the network 312 therefore comprises a plurality of grid cells 316, each grid cell formed by two vertical strip segments and two horizontal elongated strip segments of the electrically conductive strips, where the segments are interconnected at their corners to form square or rectangular grid cells. Each grid cell 316 encloses a corresponding PC cell. The width d (see FIG. 3C) of the electrode strips in electrode networks 312 is about 1 to 100 μm. Each of the Photonic Crystal (PC) cells 315 is enclosed by a corresponding one of the grid cells in each of the electrode networks 312. Therefore there are many photonic crystal cells 315 in each chip. The size of each PC cell ranges from 1 to 100 μm on each side. The holes in a triangular array as indicated by 321 are created inside the PC cell and beneath the electrodes as shown in FIG. 4A. Other hole arrays with other shapes such as square, and rectangular grids, polygonal grids and Archimedean-like lattice are also usable in this and other embodiments described herein. For a detailed description of Archimedean-like lattice, please see S. David et al., “Wide angularly isotropic photonic bandgaps obtained from two-dimensional photonic crystals with Archimedean-like tilings,” Optical Society of America, Optics Letters, vol. 25, no. 14, July 2000, pp 2-4.

The ITO layer 126 is used to spread the injection current supplied by the electrode over the full photonic crystal region. Therefore the current injection region, i.e. emitting region, overlaps the photonic crystal region, i.e. light extraction region.

In another embodiment, there is no hole beneath the electrode as shown in FIG. 4B. Current is injected by means of a current source (connection between the source and the electrodes not shown). The ITO layer 126 and ultra-thin metal layer 125 in FIG. 1 can be either kept or omitted for this case (the ITO layer is removed from FIG. 4B). Therefore the current injected primarily runs from the electrode 312 through the active layer 121 to the second electrodes 322 near the substrate, without passing through the portion of the epitaxial structure of the solid state light emitting system where the photonic crystal region is located. The photonic crystal region, which has holes, may have higher electrical resistance such that it is preferable to pass the current along paths away from this region. In this embodiment, the current injection region is substantially segregated from the photonic crystal region, which functions to extract light from the waveguide. One of advantages of this embodiment is to avoid the carrier (holes or electrons) loss in the photonic crystal region due to the defect and depletion on and near hole surfaces. The width of the electrode strips in network 312 (see FIG. 3C) is also optimized to have sufficient photons emitted in the active region underneath but having sufficient separation between the strips to allow the photons to travel between the electrode strips to reach the PC cell to emerge from the solid state light emitting system to be used for various purposes (such as illumination) without being significantly reabsorbed. The other advantage of this embodiment is that it allows the current injected into the chip to be at elevated current density without overheating the semiconductor layers.

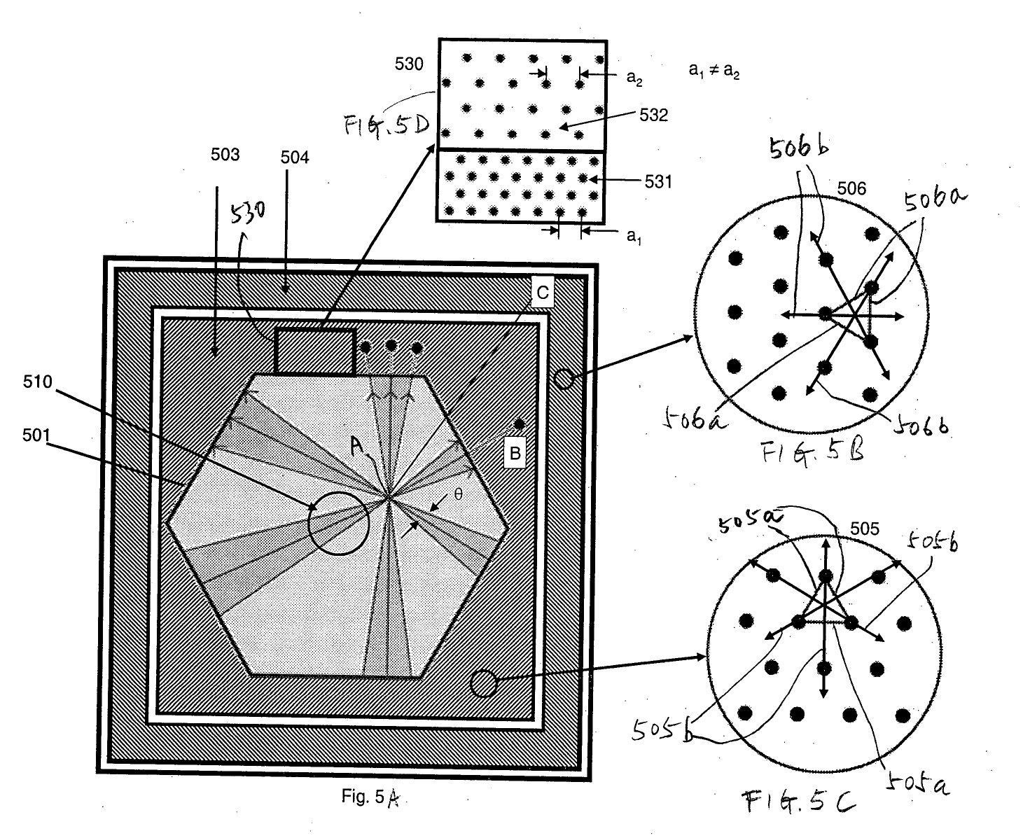

Inside the chip, the geometrical shapes of photonic crystal cells and electrodes can be arranged in many ways for the sake of optimizing optical and electrical performance of the solid state light emitting chip. FIGS. 5A is a top view of a light emitting chip that shows an example of a single hexagonal cell 501 in the chip, where the cell is surrounded by two Photonic crystal structures 503 and 504, whose triangular lattice patterns are in different orientations as indicated by 505 and 506, respectively illustrated in FIGS. 5B and 5C. In one embodiment, the chip in FIG. 5A is of a type analogous to that in FIG. 4B, where there are no holes beneath the electrode 510. Where an ITO layer is employed connecting the electrode 510 to the layers underneath (e.g. contact, cladding, waveguide and active layers as shown in FIG. 2), the ITO layer may be hexagonal in shape and is co-extensive with and defines the cell 501. Preferably, there are no holes underneath the ITO layer.. The hexagonal cell shape allows the photonic crystal to interact with photons from all directions more effectively. In the center of the Hexagonal cell 501 is an electrode 510. The current is injected across the electrode 510, spread out over the ITO layer on the surface of the Hexagonal cell and finally enters the active layer beneath and then to layers below the active layer and eventually to an electrode (not shown) different from electrode 510. When holes and electrons are recombined at a point or location A inside the active layer (similar to layer 121 in FIG. 2) as indicated in FIG. 5A, light is emitted spontaneously from the location and captured in the waveguide structure. The light so emitted is allowed to propagate in all directions along the waveguide layers.

According to the principle of interaction of light with triangular photonic crystal structures, such as those illustrated in 506 and 507, the interaction with the PC structure is most effective if the light is incident in a direction perpendicular to any of three sides of the equilateral triangle as illustrated by the lines 505a and 506a joining the elements (shown as black dots in FIGS. 5B, 5C and 5D) of the crystal structures 505 and 506 in FIGS. 5B and 5C. The arrows 505b and 506b in FIGS. 5B and 5C indicate the directions of light propagation that would have the highest degree of interaction with the PC structures for extracting the light from the chip for illumination or other purposes. Light incident on the lines such as 505a and 506a joining the elements of the crystal structures in directions at small deviations from the perpendicular directions is also extracted with longer traveling length inside the photonic crystal. For a perfect triangular photonic crystal system, the effective incident angle θ is about 30 degrees. Geometrically there are six sectors emanating from each point light source as indicated by Point or location A. For instance, a light ray within a sector will be extracted in the first photonic structure 503 as indicated by Point B. In contrast, a light ray outside a sector will propagate through the first PC structure 503 and end up to be extracted in the second PC structure 504 as indicated at Point C. The lattice constant of the second PC array 504 is substantially the same as that of the first PC array 503, but the orientations of two arrays is preferably about 30 degree rotated with respect to each other (see their blow-up views 505 and 506 in FIGS. 5B and 5C) and are complementary orientations.

By implementing two or more PC arrays with the same or substantially the same lattice constant but in different geometrical orientations to enhance orientation-dependent extraction, light propagating along the waveguide structures and being associated with one particular or a few related modes can be almost entirely extracted if such light has not yet been reabsorbed by the waveguide structure. Similar complementary orientations can also be defined for PC structures that are not equilateral triangular in shape (such as square, rectangular, or other polygonal shapes or Archimedean-like tiles) in a manner that will be evident to those skilled in the art. This method of providing PC structures with complementary orientations for maximizing extraction is also applicable to other PC arrays such as those with square, rectangular, and other polygonal patterns and or those that form Archimedean-like lattices as long as extraction efficiency of such PC arrays also exhibits angular dependence.

Light may be emitted by combination of holes and electrons at locations in the active layer underneath the hexagonal ITO layer in addition to location A shown in FIG. 5A. It is noted that such locations are surrounded by two or more regions (e.g. 503 and 504) with PC structures therein.

FIG. 1 illustrates an epitaxial structure in the present invention which structure comprises a stack of layers, including active, waveguide, cladding, DBR, contact and other layers. This stack of layers is able to support a fundamental mode and a few lower-order modes. These modes propagate along this multiple-layer waveguide structure with different propagation constants and effective indices. Therefore a pre-selected set of parameters of PC structure such as array pattern, lattice constant, lattice orientation and hole diameter is more effective in the extraction for one particular mode than other modes. In other words, a PC structure with one set of parameters may be more effective in extracting light power from one particular mode than another PC structure with a different set of parameters. Hence, it is possible to design a chip where different groups of PC structures with sets of parameters of different values are employed, and where each group of PC structures with a particular set of parameter values is selected to optimally extract light from a particular corresponding propagation mode. To maximize light extraction, it is also desirable to extract light power from the lower order modes in addition to the light power from the fundamental mode. In the present invention, several different PC structures with sets of different parameter values can be incorporated in a chip to effectively extract light power from their different corresponding modes, including the lower order modes and the fundamental mode. For example, the PC structure 503 in FIG. 5A can be composed of several PC arrays with different parameters so that the light power associated with both the fundamental modes and a few lower-order modes are effectively extracted. The scheme of implementing a multiple of PC structures is also applicable to the second PC structure 504. The geometrical arrangement of several PC arrays in 503 or 504 are aimed to have the optimal extraction with small space occupancy. One PC array in FIG. 5A encloses the other PC array as indicated by 530 is one of choices. In 530, triangular PC arrays 531 and 532 have their respective lattice constants, which are different.

Selected ones of the holes in the PC structure can also be filled with an optical material having an index of refraction that is different from air and from the surrounding or adjoining optical medium, such as the layers in the chip, so that the index of refraction of such material is another parameter that can be selected to optimize light extraction from the modes. Different PC arrays in the same chip can employ different optical materials having different indices of refraction.

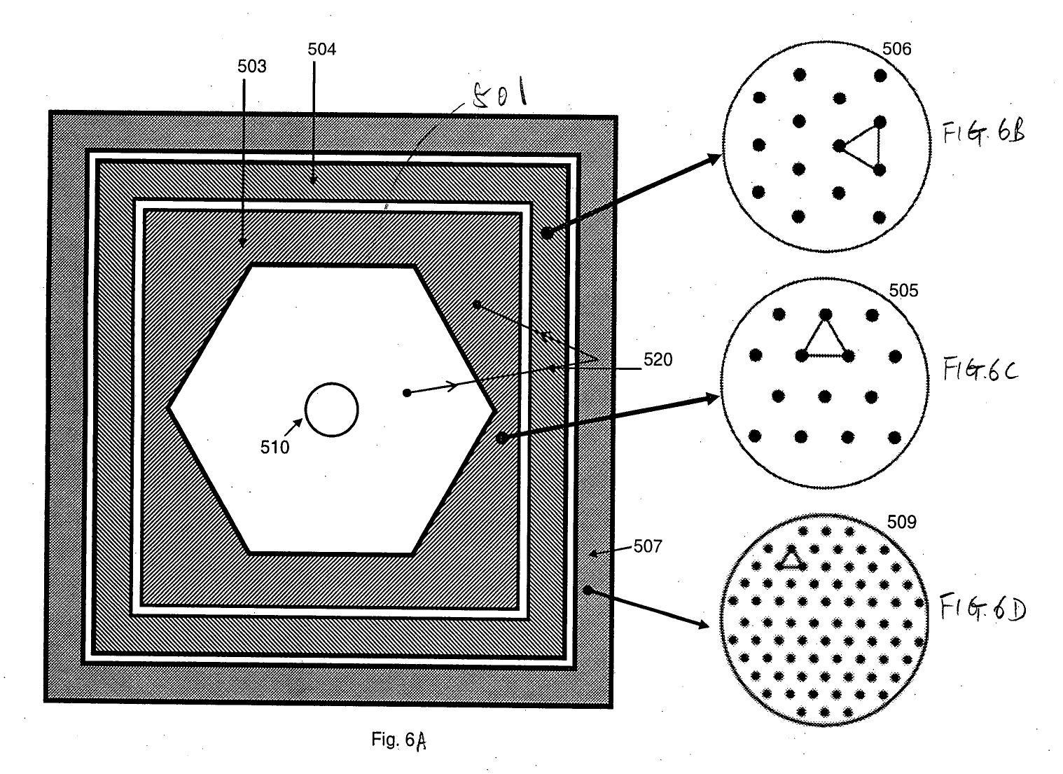

In a case where light cannot be fully extracted by two or more PC structures as shown in the FIG. 5A because of insufficient size of PC regions, one reflector 507 composed of another PC structure is added as the outside frame (i.e. surrounding the cell 501, and PC regions 503 and 504 of the chip as indicated in FIG. 6. The lattice constant as well as the hole diameter of the reflector 507 is selected such that the PC system is located in the band gap. The un-extracted photons escaping from the extraction PC regions 503 and 504 will be therefore reflected by the reflector 507 and re-enter the extraction regions 503 and 504. The reflected photons are either extracted again by the PC structures or recycled at the active layer and then re-emitted. Such optical path is indicated by 520. A blow-up view of the triangular array of the reflector 507 is shown in 509. in FIG. 6D. Its lattice constant is different from those of 505 and 506 in regions 503 and 504 respectively as illustrated in FIGS. 6B, 6C and 6D.

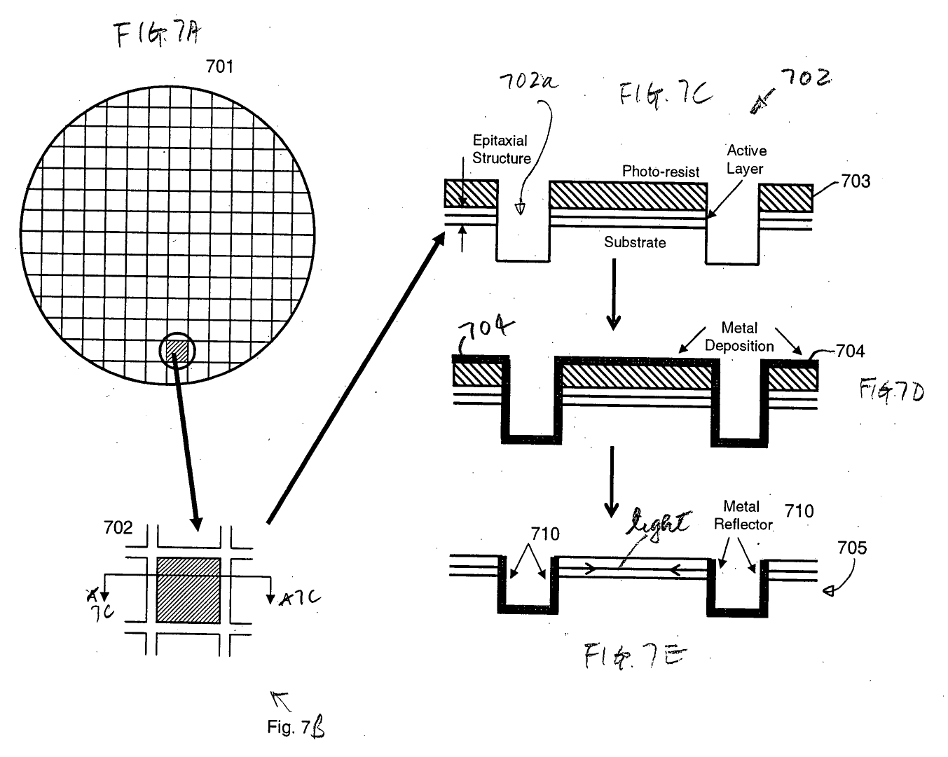

Instead of using a PC structure as a reflector, a metal layer may be applied to the four edges of a chip to reflect the light exiting the waveguide. at the chip edge. FIGS. 7A-7E illustrate how to apply metal layer(s) to the edge of a chip. By photolithography and etching, a wafer 701 (FIG. 7A) is divided into many chips one of which (702) is shown in FIG. 7B with a defined size. Trenches 702a surrounding chip 702 are therefore created by deep etching as indicated by a blow-up view of chip 702 in FIG. 7C, which is a cross-section view of chip 702 along the line 7C-7C in FIG. 7B. Photo-resist layer 703 remains on the top of the epitaxial structure from the last process step of trench creation. One or more metal layers 704 with good reflectivity such as Nickel, Gold, copper, and Titanium are deposited toward the wafer surface and surfaces of the side walls in the trenches by sputtering, electron beam deposition, or other coating methods, as illustrated in FIG. 7D. Then photo-resist is dissolved in some solvents and therefore the metal on the top of it is lifted off while the metal layers 710 inside the trench surface stays, resulting in the chip structure 705 as illustrated in FIG. 7E. Therefore, light propagating in the waveguide and/or active layer is reflected by the metal layer 710 back towards the PC regions (not shown) in the chip for further extraction. The chips in FIGS. 5A, 6A, 8A and 9A and optional reflective metal layers may be formed in a manner similar to that described immediately above.

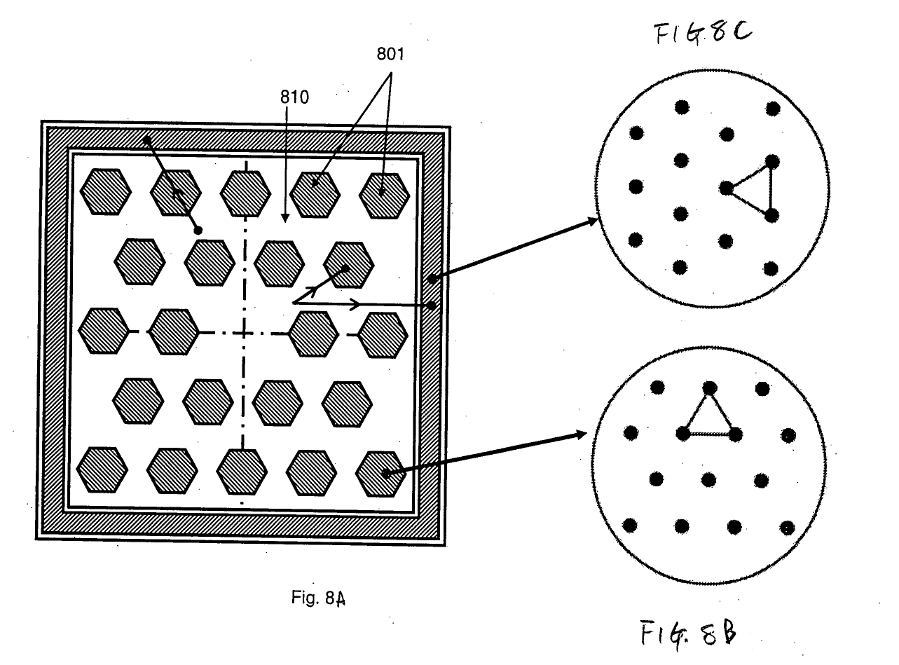

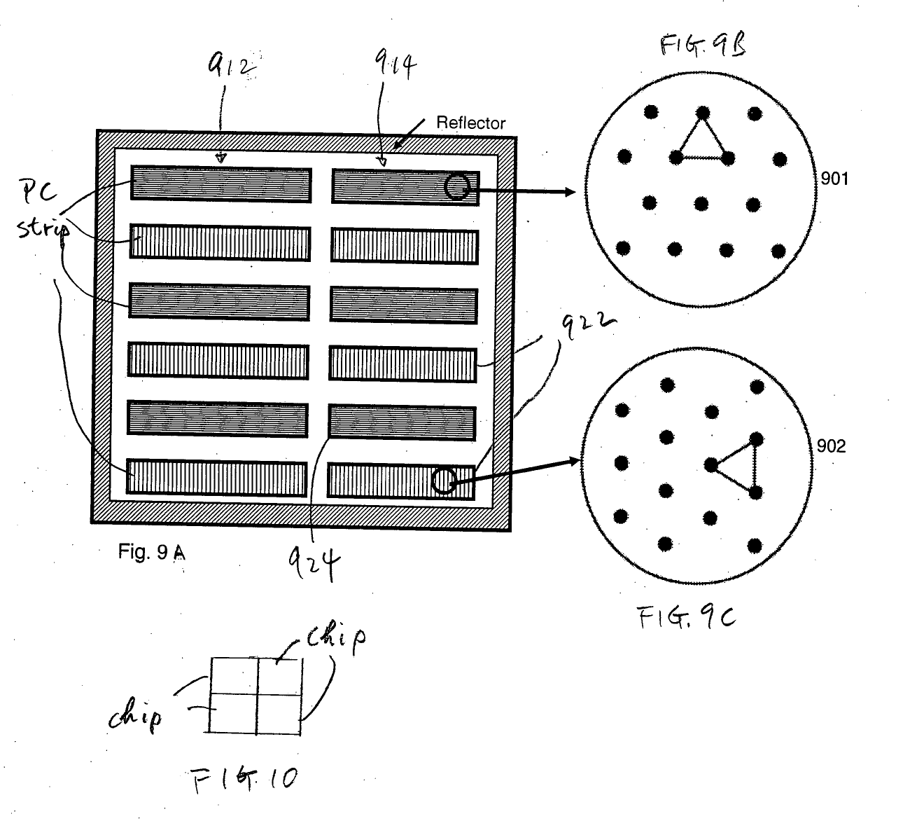

Yet another PC configuration for optimizing extraction is illustrated in FIG. 8A. As shown in such figure, a few hexagonal PC cells 801 with one kind of orientation (shown in FIG. 8B) are surrounded by current injection region 810. The outside frame of the chip is equipped with PC structures as illustrated in FIG. 8C and oriented differently from that inside the hexagonal cells 801. A reflector (not shown) can also be added to the far outside edges of the chip in FIG. 8A to reflect the un-extracted light back towards the PC regions 801 in the same manner as shown in FIGS. 6A and 7E. Furthermore, the orientations and/or other parameters described above among the PC cells 801 can be different from cell to cell. The PC cells are not necessary in a hexagonal shape. Long PC strips are also suitable as shown in FIG. 9A. In FIG. 9A, the orientation of triangular arrays in each PC strip is alternating from strip to strip as indicated by 901 and 902 in FIGS. 9B and 9C. Thus, the PC strips are arranged in columns 912 and 914, where each pair (e.g. pair 922) of strips with PC arrays with the same parameters such as orientation is separated by another strip (e.g. 924) with PC arrays with parameter(s) that are different from those of such pair.

As noted above, the substrate material is typically GaAs for red or yellow light emission structures and Sapphire, GaN or SiC for UV, blue and green light emission structures. In order to generate light of multiple colors, or to generate light by mixing light of different colors, multiple chips are used in a single device where the chips are made from different substrate materials. FIG. 10 is a schematic view of such a device with four chips, where at least two of such chips emit light of different wavelengths. By causing the chips to emit light of different colors sequentially, it is possible to display images of multiple colors. Alternatively, the chips can be caused to emit light that can be blended together to obtain light having the color of choice, such as white light. The chips in FIG. 10 may have the construction of any one of the embodiments described herein and made from processes described herein. While four chips are shown in FIG. 10, it will be understood that more or fewer chips may be employed; all such variations are within the scope of the invention.

While the invention has been described above by reference to various embodiments, it will be understood that changes and modifications may be made without departing from the scope of the invention, which is to be defined only by the appended claims and their equivalents. All references referred to herein are incorporated by reference herein in their entireties.

1. A solid state light emitting device comprising:
an active layer emitting light in response to current injected into the layer;
a first structure adjacent to the active layer, said structure and said active layer trapping the light generated by the active layer; and
a second structure extracting the light that is trapped by the first structure, said second structure comprising a plurality of photonic crystal arrays with different parameters.

2. The device of claim 1, wherein two or more of the plurality of photonic crystal arrays have different orientations.

3. The device of claim 1, wherein two or more of the plurality of photonic crystal arrays have complementary orientations.

4. The device of claim 1, wherein two or more of the plurality of photonic crystal arrays have different lattice constants.

5. The device of claim 4, wherein two or more of the plurality of photonic crystal arrays have different orientations.

6. The device of claim 1, said second structure comprising three photonic crystal arrays with different parameters, wherein at least two of the three photonic crystal arrays have different orientations and at least two of the three photonic crystal arrays have different lattice constants.

7. The device of claim 1, wherein one of the plurality of photonic crystal arrays comprises elements and is arranged so that lines joining the elements of the one array form polygons or Archimedean-like tiles.

8. The device of claim 1, wherein each of at least some of the plurality of photonic crystal arrays comprises elements and is arranged so that lines joining the elements of such array form polygons or Archimedean-like tiles.

9. The device of claim 8, wherein each of said some of the plurality of groups of photonic crystal arrays includes a triangular, square or rectangular array.

10. The device of claim 8, wherein each of said some of the plurality of groups of photonic crystal arrays includes an equilateral triangular array.

11. The device of claim 10, wherein the equilateral triangular arrays of two of said some of the plurality of photonic crystal arrays are oriented so that their orientations are about 30 degrees rotated relative to each another.

12. The device of claim 1, said second structure comprising a plurality of arrays of an optical media or medium with one or more indices of refraction that are different from an adjoining optical medium.

13. The device of claim 12, wherein the optical media of at least two of said plurality of arrays have different indices of refraction.

14. The device of claim 12, said second structure comprising a plurality of arrays of holes in a layer adjacent to the active layer, in the first structure or in the active layer.

15. The device of claim 1, said device comprising an electrode injecting current to locations in the active layer or another layer near the active layer, said locations being located adjacent to said at least some of the plurality of photonic crystal arrays with different parameters.

16. The device of claim 15, wherein two or more of the plurality of photonic crystal arrays have different orientations.

17. The device of claim 15, wherein two or more of the plurality of photonic crystal arrays have complementary orientations.

18. The device of claim 15, wherein two or more of the plurality of photonic crystal arrays have different lattice constants.

19. The device of claim 18, wherein two or more of the plurality of photonic crystal arrays have different orientations.

20. The device of claim 15, wherein said locations are substantially surrounded by said at least some of the plurality of photonic crystal arrays with different parameters.

21. The device of claim 20, wherein said locations are substantially surrounded by a first region of photonic crystal arrays with a first parameter, wherein the first region is surrounded by at least a second region of photonic crystal arrays with a second parameter different from the first parameter.

22. The device of claim 15, wherein said plurality of arrays are distributed throughout the chip.

23. The device of claim 22, wherein said plurality of arrays are hexagonal in shape.

24. The device of claim 22, wherein said plurality of arrays are elongated in shape.

25. The device of claim 24, wherein said plurality of arrays are arranged in columns, where each of at least some of pairs of arrays with a first parameter in a column are separated by at least one array with a second parameter different from the first parameter.

26. The device of claim 1, further comprising a third structure that reflects light that is emitted from the active layer and that is not extracted when passing through the photonic crystal arrays back towards the arrays.

27. The device of claim 26, said third structure comprising a photonic crystal structure or a mirror surface.

28. The device of claim 26, said third structure surrounding the active layer and/or the first structure, so that light emitted by the active layer and not extracted by the photonic crystal arrays are reflected back towards such arrays.

29. The device of claim 1, wherein the first structure contains substantially a single optical mode or a few lower-order optical modes, and traps the light generated in the said optical mode(s).

30. The device of claim 1, wherein the first structure comprises at least one waveguide layer.

31. The device of claim 1, further comprising at least one conductive layer having a hexagonal shape injecting current to locations in the active layer or a layer near the active layer, at least one of the plurality of arrays forming a triangular pattern and surrounding said locations.

32. The device of claim 1, wherein the different parameters comprise two or more of the following: array pattern, lattice constant, lattice orientation, size and index of refraction of array element.

33. A method for making a solid state light emitting device, comprising:
providing an semiconductor body, said body having an active layer that emits light when electrical current is injected into the layer, and at least another layer adjacent to the active layer;
forming at least one array of holes in said at least another layer to provide photonic crystal arrays; and
forming reflective structures each surrounding a portion of the active layer and some of the holes in the array.

34. The method of claim 33, wherein said reflective structures are formed by providing a resist layer on the body, developing a pattern of indentations onto the resist layer, and etching into the resist layer and the body to form trenches, depositing a light reflective layer onto surfaces of the trenches and removing the resist layer together with portions of the reflective layer attached to the resist layer.

35. A solid state light emitting device comprising a plurality of chips, each chip comprising:
an active layer emitting light in response to current injected into the layer;
a first structure adjacent to the active layer, said structure and said active layer trapping the light generated by the active layer; and
a second structure extracting the light that is trapped by the first structure, said second structure comprising a plurality of photonic crystal arrays with different parameters.

36. The device of claim 35, each of at least some of said plurality of chips comprising an electrode injecting current to locations in the portion of the active layer or another layer near the active layer in such chip, said locations being located adjacent to said at least some of the plurality of photonic crystal arrays with different parameters.

37. The device of claim 36, wherein said locations are substantially surrounded by said at least some of the plurality of photonic crystal arrays with different parameters.

38. The device of claim 37, wherein said locations are substantially surrounded by a first region of photonic crystal arrays with a first parameter, wherein the first region is surrounded by at least a second region of photonic crystal arrays with a second parameter different from the first parameter.

39. The device of claim 36, wherein said plurality of arrays are distributed throughout each of said at least some of said plurality of chips.

40. The device of claim 39, wherein said plurality of arrays in each of said at least some of said plurality of chips are hexagonal in shape.

41. The device of claim 39, wherein said plurality of arrays in each of said at least some of said plurality of chips are elongated in shape.

42. The device of claim 41, wherein said plurality of arrays in each of said at least some of said plurality of chips are arranged in columns, where each of at least some of pairs of arrays with a first parameter in such chip are separated by at least one array with a second parameter different from the first parameter.

43. The device of claim 35 wherein two or more of the plurality of photonic crystal arrays in each of said some of said plurality of chips have different orientations.

44. The device of claim 35, wherein two or more of the plurality of photonic crystal arrays have complementary orientations.

45. The device of claim 35, wherein two or more of the plurality of photonic crystal arrays in each of said some of said plurality of chips have different lattice constants.

46. The device of claim 45, wherein two or more of the plurality of photonic crystal arrays in each of said some of said plurality of chips have different orientations.

47. The device of claim 35, each of at least some of said plurality of chips further comprising a third structure that reflects light that is emitted from the active layer in such chip and that is not extracted when passing through the photonic crystal arrays in such chip back towards the arrays.

48. The device of claim 35, wherein at least two of said plurality of chips emit light of different wavelengths.

49. The device of claim 35, wherein said plurality of chips emit light within more than one of the red, yellow, green and blue wavelength ranges.
